(19) United States
(12) Patent Application Publication
(10) Pub. No.: US 2007/0257716 A1
(43) Pub. Date: Nov. 8, 2007

(54) Dft Technique for Stressing Self-Timed Semiconductor Memories to Detect Delay Faults

(76) Inventors: Mohamed Azimane, Eindhoven (NL); Ananta Majhi, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(21) Appl. No.: 10/591,193

(22) PCT Filed: Mar. 3, 2005
(86) PCT No.: PCT/IB05/50800

§ 371 Date: Aug. 30, 2006

Related U.S. Application Data
(60) Provisional application No. 60/550,416, filed on Mar. 5, 2004.
(60) Provisional application No. 60/590,402, filed on Jul. 21, 2004.

(51) Int. Cl. H03L 7/00

(52) U.S. Cl. 327/144

(57) ABSTRACT

The present invention relates to a test system (100) interposed between a clock monitor self-timed memory. In an example embodiment, the test system (100) receives an internal clock signal (104) from the clock monitor (152), an external clock signal (CL) and a control signal (CS). A multiplexer (110) of the test system provides in dependence upon the control signal (CS) the internal clock signal (104) to the internal memory block (125) during a normal mode of operation of the self-timed memory and the external clock signal (CL) to the internal memory block (125) during a test mode (108) of the self-timed memory. The test system (100) enables control of the clock cycle of the internal memory block (125) by directly applying the external clock signal (CL) during test mode. Thus, the internal memory block is stressed properly enabling the detection of small delay faults.

This application claims priority of provisional application titled, “DFT Technique for Stressing Self-Timed Semiconductor Memories to Detect Delay Faults,” (Ser. No. 60/550,416) filed on Mar. 5, 2004 and is incorporated by reference in its entirety.

This invention relates to the field of testing of semiconductor memories and in particular, to a design for test (DFT) method for detecting delay faults in semiconductor memories.

Systematic and automatic testing of integrated circuits becomes increasingly important. With each new generation of integrated circuits component density, number of system functionalities, and clock speed are substantially increased. Integrated circuits have reached such complexity and speed that process defects are no longer detectable using even the most exhaustive and expensive conventional testing procedures. However, customers will not accept products that show their hidden defects in operational use, thereby rendering, for example, life support systems or aircraft control systems unreliable.

Self-timed semiconductor memories are well known in the art and are preferably used in high-speed applications. The read and write cycles in the self-timed memories are triggered by either the positive or the negative edge of a clock signal. The memory cycle continues until its completion, independent of the clock edge. Application of a duty cycle different than 50% has an effect on the detection of delay faults. A duty cycle smaller than 50% enables detection of delay faults causing slow-to-rise behavior in the memory address decoder. A duty cycle higher than 50% enables detection of delay faults causing slow-to-fall behavior in the memory address decoder. Furthermore, the clock duty cycle also stresses sense amplifiers, bit lines, pre-charge circuitry, and discharge circuitry, substantially increasing delay faults detection. It is known in the art that “at-speed” testing stresses the delay faults when the correct test patterns are implemented. However, implementation of a Built-In-Self-Test (BIST) for high frequency implies a substantial increase in area for the BIST, which is unacceptable for most applications. However, changing the duty cycle of the external clock has no effect on the detection of delay faults for self-timed semiconductor memories, because the positive or negative edge of the external clock does not control the end of the clock cycle. In self-timed memories termination of the read/write operation is determined internally depending on the dummy blocks. Therefore, it is not possible to control the sensitizing operation by increasing or reducing the duty cycle of the external clock making memory test a difficult task for detecting slow-to-rise and slow-to-fall delays.

There exists a need to provide a solution that overcomes the shortcomings of at-speed testing for detecting slow-to-rise and slow-to-fall delays in self-timed semiconductor memories.

The present invention has been found useful in detecting slow-to-rise and slow-to-fall delays in self-timed semiconductor memories other than at-speed testing. The invention provides a technique for increasing the controllability of an internal block of a self-timed semiconductor memory such that the duty cycle becomes a parameter for detecting slow-to-rise and slow-to-fall delays.

In an embodiment according to the present invention, there is a method for providing an external clock signal to an internal memory block of a self-timed memory. The method comprises receiving an internal clock signal from a clock monitor of the self-timed memory, receiving an external clock signal, and receiving a control signal. In dependence upon the control signal, the internal clock signal to the internal memory block during a normal mode of operation of the self-timed memory, and the external clock signal to the internal memory block during a test mode of the self-timed memory are provided.

In another embodiment according the present invention there is a self-timed memory that comprises an internal memory block. There is a clock monitor for receiving an external clock signal and for providing an internal clock signal in dependence thereupon to the internal memory block. A test system is interposed between the clock monitor and the internal memory block. The test system comprises an internal clock signal input port in signal communication with the clock monitor for receiving the internal clock signal, an external clock signal input port for receiving the external clock signal, a control signal input port for receiving a control signal, an out put port in signal communication with the internal memory block; and, a multiplexer in signal communication with the internal clock signal input port, the external clock signal input port, the control signal input port and the output port, the control circuitry for receiving the internal clock signal, the external clock signal, and the control signal, and for providing, in dependence upon the control signal, the internal clock signal via the output port to the internal memory block during a normal mode of operation of the self-timed memory, and for providing the external clock signal to the internal memory block during a test mode of the self-timed memory.

In yet another embodiment according to the present invention there is a self-timed memory that comprises at least an internal memory block, a clock monitor for receiving an external clock signal and for providing at least an internal clock signal in dependence thereupon to the at least an internal memory block, and a test system interposed between the clock monitor and the at least an internal memory block. The test system comprises, at least an internal clock signal input port in signal communication with the clock monitor for receiving at least an internal clock signal, an external clock signal input port for receiving the external clock signal, a control signal input port for receiving a control signal, at least an out put port in signal communication with the at least an internal memory block; and, control circuitry in signal communication with the at least an internal clock signal input port, the external clock signal input port, the control signal input port and the at least an output port, the control circuitry for receiving the at least an internal clock signal, the external clock signal, and the control signal, and for providing, in dependence upon the control signal, the at least an internal clock signal via the at least an output port to the at least an internal memory block during a normal mode of operation of the self-timed memory, and for providing the external clock signal to at least one of the at least an internal memory block during a test mode of the self-timed memory.

The above summaries of the present invention are not intended to represent each disclosed embodiment, or every aspect, of the present invention. Other aspects and example embodiments are provided in the figures and the detailed description that follow.

The invention may be more completely understood in consideration of the following detailed description of various embodiments of the invention in connection with the accompanying drawings, in which:

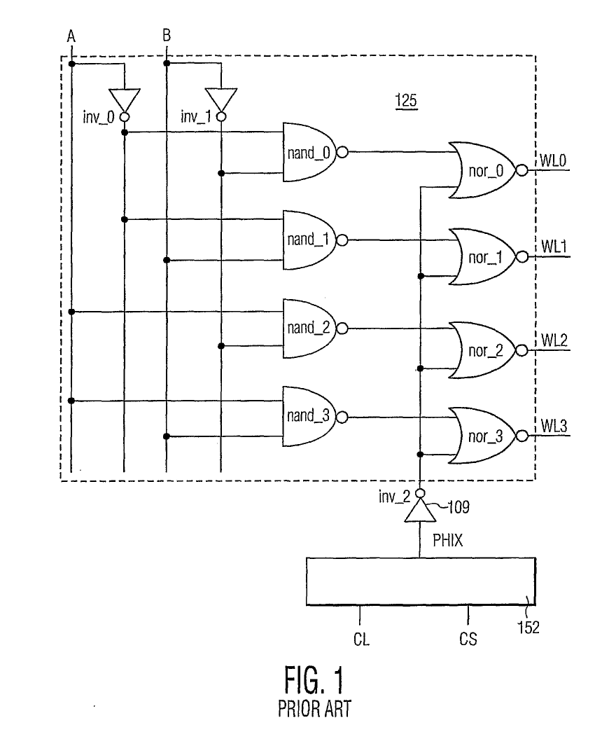

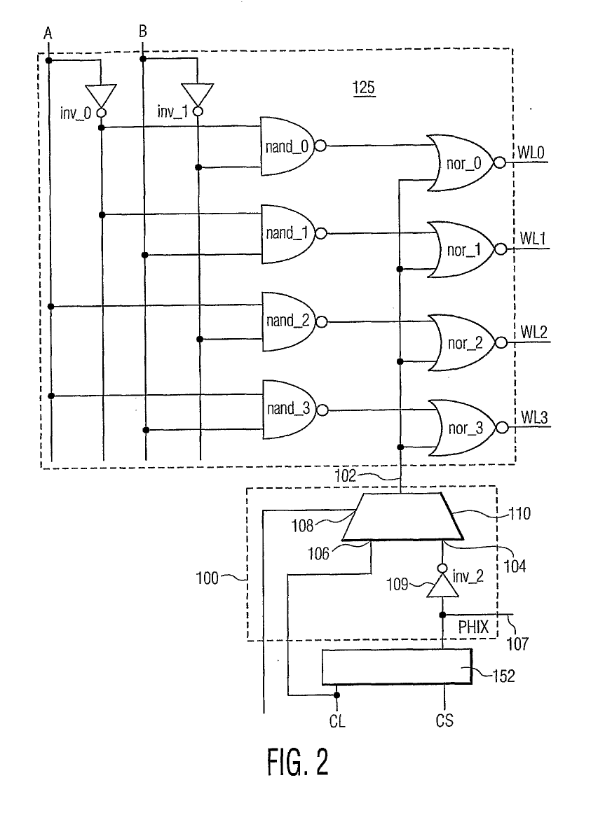

FIG. 1 (Prior Art) is a simplified block diagram schematically illustrating an address decoder with a clock monitor for generating an internal clock signal;

FIG. 2 is a simplified block diagram schematically illustrating the address decoder shown in FIG. 1 with a test system according to the invention;

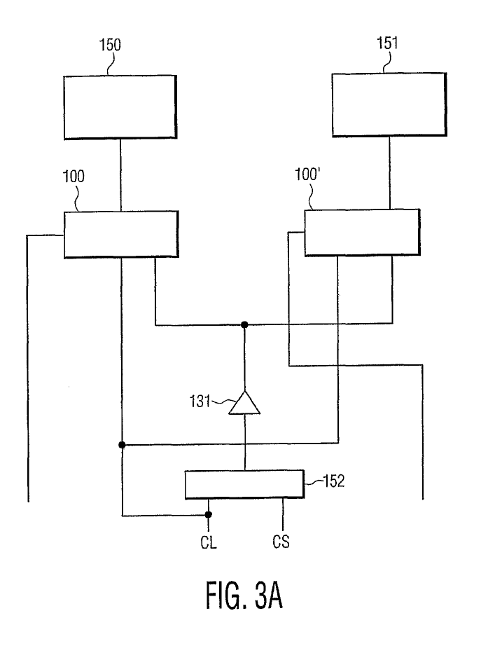

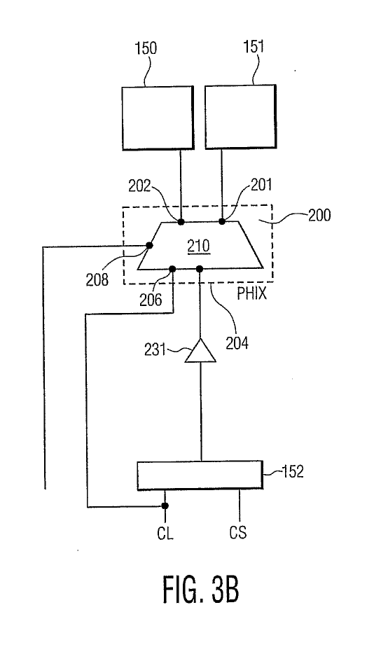

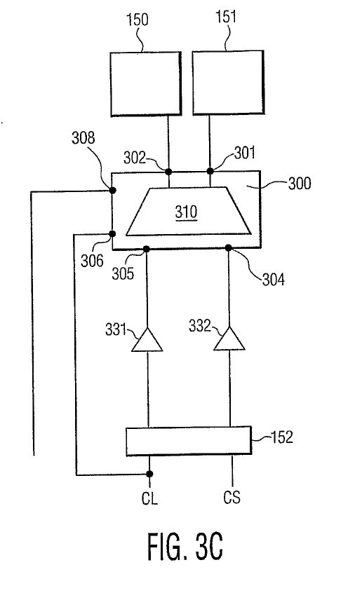

FIGS. 3A-3C are simplified block diagrams schematically illustrating various embodiments of the test system according to the invention; and

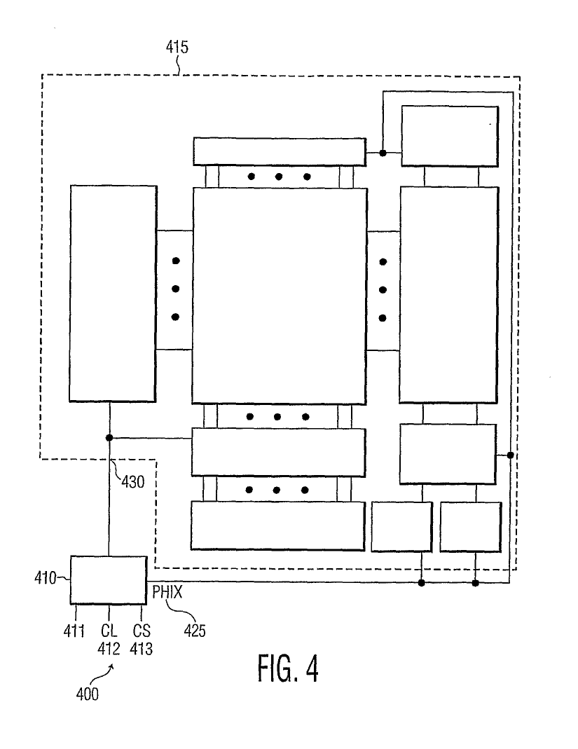

FIG. 4 shows a detailed self-timed memory block diagram coupled with the test system according to an embodiment of the present invention; and

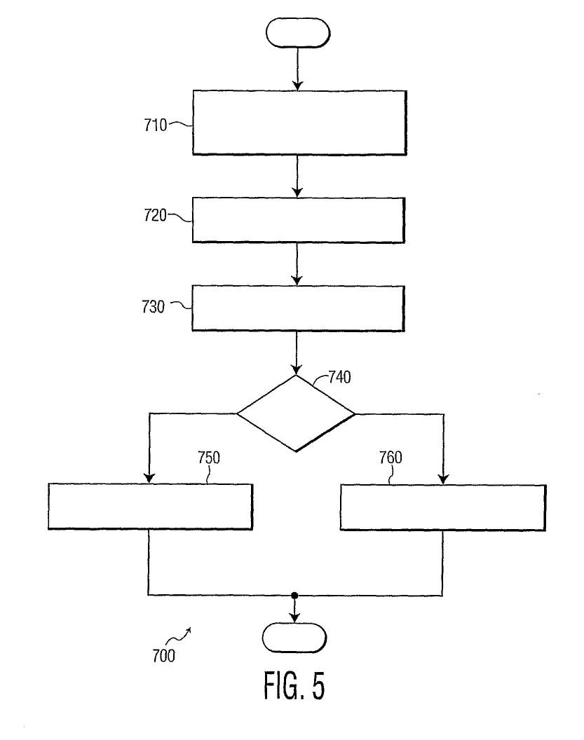

FIG. 5 is flowchart of the steps in implementing an embodiment according to the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

In the self-timed semiconductor memories the duty cycle effect disappears due to the self-timed operation. The termination of a read/write operation is internally determined. Therefore, it is impossible to control the beginning or the end of an action in an internal memory block of a self-timed memory making memory test a difficult task for detecting slow-to-rise and slow-to-fall delays.

This drawback of the self-timed memories is overcome by incorporating a test system for testing self-timed memories according to the invention. The test system is based on a Design For Test (DFT) technique that enables control of an internal memory block such that the duty cycle becomes a parameter for detecting slow-to-rise and slow-to-fall delays. By enabling external control of the beginning and end of internal functions of the self-timed memory using the test system according to the invention it is possible to increase or reduce the duty cycle for detecting delay faults. Preferably, the test system is implemented for modifying the duty cycle of internal memory blocks that have a substantial impact on the detection of delay faults. For example, by controlling the address decoder it is possible to detect small delay faults in the word lines of the memory due to weak resistive open defects.

Referring to FIG. 1, a 2-to-4 address decoder 125 controlled by an internal clock signal PHIX is shown. Control logic, clock monitor 152 of the address decoder 150 is initiated based on the positive or negative edge of an external clock signal CL. The control logic 152 then generates the internal clock signal PHIX. Word line activation and deactivation is controlled depending on the positive or negative edge of the internal clock signal PHIX. Hence, the activation and deactivation of the word lines is independent of the external clock signal CL. Therefore, the detection of slow-to-rise and slow-to-fall delay faults depends on the duty cycle of the internal clock signal PHIX and not the external clock signal CL. The chip select CS is a signal that activates an operation of the memory. In one example memory, when CS is a logic “1”, the memory is activated for read or write operation. In other example memory, when CS is a logic “0,” the memory is activate for read or write operation. Consequently, depending upon the design of the memory, inv_2 (109) may be replaced with a buffer instead.

Referring to FIG. 2, a test system 100 according to the invention connected to the 2-to-4 address decoder 125 is shown. The test system 100 includes a clock signal input ports 104 and 106 for receiving the internal clock signal PHIX from the clock monitor 152 and the external clock signal CL, respectively. Depending on a control signal received at control input port 108 a multiplexer 110 provides via output port 102 the internal clock signal 107 (PHIX) or the external clock signal CL to the address decoder 125. Depending on the received control signal, the multiplexer 110 provides the internal clock signal PHIX to the address decoder 125 in normal mode or the external clock signal CL during test mode. Interposing the test system 100 between the clock monitor 152 and the address decoder 125 enables control of the clock cycle of the address decoder 125, by directly applying the external clock signal CL to the address decoder 125 during test mode. Thus, the beginning and the end of the activation and deactivation of the word lines is easily controlled by the external clock signal CL enabling the detection of delay faults. As is evident, the test system is easily extended to cover a plurality of internal memory blocks that are controlled by the internal memory clock such as sense amplifier, column and bank decoder, pre-charge and discharge circuitry, and input/output latches.

Referring to FIGS. 3A to 3C, three embodiments of the test system according to the present invention are shown coupled to two internal memory blocks 150 and 151, respectively. For simplicity only, the illustrations in FIGS. 3A to 3C are limited to two internal memory blocks. As is evident, the embodiments may be expanded to more than two internal memory blocks.

In the implementation, shown in FIG. 3A, two test systems 100, 100 are interposed between the clock monitor 152 and each of the internal memory blocks 150 and 151, i.e. one test system is used for controlling one internal memory block 150 and 151, respectively. A buffer 131 couples the clock monitor 152 to the inputs of test systems 100, 100′.

Alternatively, as shown in FIG. 3B, one test system 200 having two output ports 201 and 202, respectively, is interposed between the clock monitor 152. Depending on a control signal received at control input port 208 multiplexer 210 provides via the output ports 201 and 202 the internal clock signal PHIX, received at input port 204, or the external clock signal CL, received at input port 206, to the internal memory blocks 150 and 151, respectively. Depending on the received control signal the test system 200 provides the internal clock signal PHIX to the internal memory blocks 150 and 151 in normal mode or the external clock signal CL during test mode. A buffer 231 couples one output of the clock monitor 152 to an input of the test system 200.

In the example embodiment, shown in FIG. 3C, the test system 300 receives via input ports 304 and 305 two internal clock signals for the internal memory blocks 150 and 151, respectively. Depending on a control signal received at control input port 308 multiplexer 310 provides via output ports 301 and 302 the internal clock signals received at the input ports 304 and 305, or the external clock signal CL, received at input port 306, to the internal memory blocks 150 and 151, respectively. Buffers 331, 332 couple outputs of the clock monitor 152 with inputs 304, 305 of the test system 300.

Referring to FIG. 4. A test system 410 according to an embodiment of the present invention is coupled to a self-timed memory 415. The test system 410 generates the clock 430 for the address decoders and the internal clock 425 (PHIX) for controlling the other blocks of the memory 415. The test system 410 has a test mode input 411, input for external clock signal 412, and chip select 413.

In another example embodiment, a control signal input port and external clock signal input port are connected to a test circuitry implemented on a same chip as that of the memory. The test circuitry controls the mode of operation of the test system. For example, the test circuitry provides a control signal for starting the test mode, a control signal for terminating the test mode and, optionally, during the test mode. In an example embodiment, the test system operates in normal mode when no control signal is received. Provision of a control signal during the test mode allows, for example, testing of a plurality of internal memory blocks using one test system by switching provision of the external clock signal to different internal memory blocks according to a predetermined test pattern. The test circuitry generates an external clock signal according to a predetermined test pattern for detecting delay faults, having, for example, a duty cycle lower or higher than the 50% duty cycle of an internal memory block, and provides it to the test system during test mode.

The test system according to the invention provides an easy to implement DFT technique for stressing internal memory blocks with an external clock signal in test mode substantially increasing the capability of detecting delay faults in self-timed memories. The circuitry of the test system is easily integrated into existing designs of self-timed semiconductor memories using existing technology. Furthermore, the test system substantially increases the test capability while requiring minimum area overhead for its implementation. The process of implementing an embodiment of the present invention may be found in FIG. 5. A method 700 provides an external clock signal to an internal memory block of a self-timed memory. An internal clock signal is received (710) from the clock monitor of the self-timed memory. An external clock signal is received (720). A control signal is received (730). Depending upon the control signal state (740), an internal clock signal may be provided to the internal memory block during a normal mode of operation (750) of the self-timed memory or an external clock signal to the internal memory block during a test mode (760) of the self-timed memory.

Numerous other embodiments of the invention will be apparent to persons skilled in the art without departing from the spirit and scope of the invention as defined in the appended claims.

1. A method for providing an external clock signal to an internal memory block of a self-timed memory comprising: receiving an internal clock signal from a clock monitor of the self-timed memory; receiving an external clock signal; receiving a control signal; and, providing, in dependence upon the control signal the internal clock signal to the internal memory block during a normal mode of operation of the self-timed memory, and the external clock signal to the internal memory block during a test mode of the self-timed memory.

2. A method for providing an external clock signal to an internal memory block of a self-timed memory as defined in claim 1 wherein the external clock signal received during test mode is generated according to a predetermined test pattern.

3. A method for providing an external clock signal to an internal memory block of a self-timed memory as defined in claim 2 wherein the external clock signal received during test mode comprises a duty cycle lower than a 50% duty cycle of the internal memory block.

4. A method for providing an external clock signal to an internal memory block of a self-timed memory as defined in claim 2 wherein the external clock signal received during test mode comprises a duty cycle higher than a 50% duty cycle of the internal memory block.

5. A method for providing an external clock signal to an internal memory block of a self-timed memory as defined in claim 1 wherein the internal clock signal is provided to the internal memory block in absence of a control signal.

6. A method for providing an external clock signal to an internal memory block of a self-timed memory as defined in claim 1 wherein a control signal indicating initiation of the test mode is provided.

7. A method for providing an external clock signal to an internal memory block of a self-timed memory as defined in claim 6 wherein a control signal indicating termination of the test mode is provided.

8. A method for providing an external clock signal to an internal memory block of a self-timed memory as defined in claim 7 wherein at least a control signal is provided during the test mode.

9. A self-timed memory comprising: an internal memory block a clock monitor for receiving an external clock signal and for providing an internal clock signal in dependence thereupon to the internal memory block; a test system interposed between the clock monitor and the internal memory block, the test system comprising: an internal clock signal input port in signal communication with the clock monitors for receiving the internal clock signal; an external clock signal input port for receiving the external clock signal; a control signal input port for receiving a control signal; an output port in signal communication with the internal memory block; and, a multiplexer in signal communication with the internal clock signal input port, the external clock signal input port the control signal input port and the output port, the control circuitry for receiving the internal clock signal, the external clock signal, and the control signal, and for providing, in dependence upon the control signal, the internal clock signal via the output port to the internal memory block during a normal mode of operation of the self-timed memory, and for providing the external clock signal to the internal memory block during a test mode of the self-timed memory.

10. A self-timed memory as defined in claim 9 wherein the clock monitor comprises an input port for receiving the external clock signal and wherein the input port is connected to the external clock signal input port of the test system.

11. A self-timed memory as defined in claim 10 comprising test circuitry in signal communication with the test system, the test circuitry for providing a control signal to the test system and for providing the external clock signal to the test system during test mode.

12. A self-timed memory as defined in claim 9 wherein the internal memory block comprises an address decoder.

13. A self-timed memory as defined in claim 9 wherein the internal memory block comprises a sense amplifier.

14. A self-timed memory as defined in claim 9 wherein the internal memory block comprises a column and bank decoder

15. A self-timed memory as defined in claim 9 wherein the internal memory block comprises a precharge and discharge circuitry.

16. A self-timed memory as defined in claim 9 wherein the internal memory block comprises input/output latches.

17. A self-timed memory comprising: at least an internal memory block; a clock monitor for receiving an external clock signal and for providing at least an internal clock signal in dependence thereupon to the at least an internal memory block; a test system interposed between the clock monitor and the at least an internal memory block, the test system comprising: at least an internal clock signal input port in signal communication with the clock monitor for receiving at least an internal clock signal; an external clock signal input port for receiving the external clock signal; a control signal input port for receiving a control signal; at least an output port in signal communication with the at least an internal memory block; and, control circuitry in signal communication with the at least an internal clock signal input port, the external clock signal input port, the control signal input port and the at least an output port, the control circuitry for receiving the at least an internal clock signal, the external clock signal, and the control signal, and for providing, in dependence upon the control signal, the at least an internal clock signal via the at least an output port to the at least an internal memory block during a normal mode of operation of the self-timed memory, and for providing the external clock signal to at least one of the at least an internal memory block during a test mode of the self-timed memory.

18. A self-timed memory as defined in claim 17 wherein the control circuitry comprises a multiplexer.

19. A self-timed memory as defined in claim 18 wherein the at least an internal memory block comprises an address decoder.

20. A self-timed memory as defined in claim 19 wherein the at least an internal memory block comprises a sense amplifier.

21. A self-timed memory as defined in claim 20 wherein the at least an internal memory block comprises a column and bank decoder.

22. A self-timed memory as defined in claim 21 wherein the at least an internal memory block comprises a precharge and discharge circuitry.

23. A self-timed memory as defined in claim 22 wherein the at least an internal memory block comprises input/output latches.

24. A self-timed memory as defined in claim 23 comprising test circuitry in signal communication with the test system, the test circuitry for providing a control signal to the test system and for providing the external clock signal to the test system during test mode.
